(19) United States
(12) Patent Application Publication
(10) Pub. No.: US 2022/0006014 A1
(43) Pub. Date: Jan. 6, 2022

(54) PIXEL ARRANGEMENT DISPLAY DEVICE AND EVAPORATION METHOD FOR IMPROVING PIXEL RESOLUTION

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ruiting HE, Wuhan, Hubei (CN)

(21) Appl. No.: 16/756,428

(22) PCT Filed: Dec. 17, 2019
(86) PCT No.: PCT/CN2019/125911

§ 371 Date: Apr. 15, 2020

(30) Foreign Application Priority Data
Nov. 26, 2019 (CN) 201911170151.0

(51) Int. Cl. H01L 51/00; H01L 51/56; H01L 27/32

(52) U.S. Cl. CPC H01L 51/0011; H01L 51/56; H01L 2227/323; H01L 27/3244; H01L 27/3211

(57) ABSTRACT

The present disclosure provides a pixel arrangement display device and an evaporation method for improving pixel resolution. The method sets a quadrangle of R pixels, G pixels, and B pixels that may be independently controlled and emitted on an evaporation substrate in order. Adjacent pixels with a same appearance and a same color are used as independent units, and a film for each of the independent units is formed by performing EL film layer evaporation through separate FMM openings, which is advantageous for manufacturing OLED displays with same resolution and higher pixel density.

### FIELD OF INVENTION

The present disclosure relates to the organic light-emitting diode (OLED) manufacturing technology field, and more particularly, to a pixel arrangement display device and an evaporation method for improving pixel resolution.

### BACKGROUND OF INVENTION

At present, most organic light-emitting diode (OLED) devices are manufactured by using a fine metal mask (FMM) for red, green, and blue (RGB) pixel electrical luminescence (EL) film evaporation. Each FMM opening corresponds to one pixel, and current mass production technology FMM designs one opening for one pixel single-layer film evaporation, as shown in FIG. 1.

In a full-color organic EL display device, an organic EL element including a light-emitting layer of each color, such as red (R), green (G), and blue (B), is generally formed as a sub-pixel arrangement on a substrate. The organic EL element selectively emits light at a desired luminance for performing full-color image display. As market demands for higher resolution, a diameter of FMM pixel openings becomes increasingly smaller, which greatly increases difficulty of controlling an FMM manufacturing process and an OLED evaporation process. When the resolution is above 300 ppi, an arrangement requires that the opening of the FMM and a connecting bridge (ribs connecting adjacent openings) to both be very small, which presents great difficulty for the processing of the mask. Moreover, alignment accuracy of the mask, shadow of the mask, and deformation of the mask due to other factors will seriously affect evaporation of an organic light-emitting material to form a finely colored pixel pattern.

In response to this problem in the industry, leading companies have been actively researching new technologies represented by laser induced thermal imaging (LITI) in order to be able to produce high-resolution OLED displays. However, there are still many insufficiencies in these new technologies, and they cannot be used in mass production presently, or generate low yield during mass production. For example, an increase in manufacturing processes and additional manufacturing processes are required, resulting in low production efficiency; or an increase in equipment and raw materials are required, and special raw materials even need to be developed, leading to increased investment and costs. Even so, these new technologies still have difficulty producing ultra-high-resolution displays above 450 ppi. At the same time, a small opening of the FMM pixel will also increase a frequency of FMM cleaning in a continuous evaporation process, resulting in reduced productivity, waste of evaporation materials, and loss of FMM due to increased cleaning times.

### SUMMARY OF INVENTION

Being directed against disadvantages of the prior art, the present disclosure provides a pixel arrangement display device and an evaporation method for improving pixel resolution. During manufacturing OLED panels with a same resolution, widths of an opening and a connecting bridge of the present disclosure are larger, which is easy to process and is not easy to deform. An increase in a distance between different pixels is beneficial to prevent color from mixing and to improve product yield. Larger margin of evaporation position is easy to perform the evaporation process, solving the reduction of productivity caused by the increase of FMM replacement frequency and reducing the FMM cleaning loss.

The present disclosure is achieved through the following technical solutions.

A pixel arrangement evaporation method for improving pixel resolution, and the evaporation method comprises steps as follows:

Step 1: utilizing adjacent pixels with a same appearance and a same color in a pixel arrangement on an evaporation substrate as independent units.

Step 2: drilling a separate fine metal mask (FMM) opening on the evaporation substrate.

Step 3: forming a film for each of the independent units by performing an electrical luminescence (EL) film layer evaporation through the separate FMM opening.

Further, when a number of the pixels in three single-color independent units is same, and all the pixel arrangements and independent units are evaporated by a same FMM opening.

Further, during the evaporation process, a plate with evaporation particles and closest to an evaporation source in the substrate is removed, and a clean plate is further added to a restriction unit at a position different from a position of the removed substrate.

Further, an opening direction of at least one first FMM opening and at least one second FMM opening is inclined toward an opposite side with one another, so that an amount of an evaporation material attached to the restriction unit is reduced for improving utilization efficiency of the evaporation material.

A pixel arrangement display device for improving pixel resolution, and the display device is used for achieving the aforementioned evaporation method for improving pixel resolution. Wherein the display device comprises an electrical luminescence (EL) display device, and the EL display device is a bottom-emission type organic EL display device that extracts light from an evaporation substrate side, which controls light emission of pixels of each color comprising red (R) pixels, green (G) pixels, and blue (B) pixels to perform full-color image display. A quadrangle of R pixels, G pixels, and B pixels that may be independently controlled and emitted are arranged on the evaporation substrate in order, and the adjacent pixels with the same appearance and the same color in the pixel arrangement on the evaporation substrate are used as independent units.

Preferably, a shape of the FMM opening is a quadrangle or a polygon other than the quadrangle.

Preferably, the FMM openings may be distributed on a same straight line.

Preferably, a number of pixels in the independent units is ≥2.

Preferably, a distance between pixels in the independent units may be increased or decreased.

Preferably, the R pixels are red quadrangle, the G pixels are green quadrangle, and the B pixels are blue quadrangle.

Advantageous effects of the present disclosure are that:

First, during manufacturing of OLED panels with a same resolution, widths of an opening and a connecting bridge are greater, making a mask of red, green, and blue pixels of the present disclosure easier to process and not easy to deform. An increase in a distance between different pixels is beneficial for preventing color from mixing and improving product yield. Larger margin of evaporation position makes it easy to perform the evaporation process, preventing a reduction of productivity caused by an increase of FMM replacement frequency and reducing loss of FMM due to cleaning.

Secondly, in a case where the mask opening width is same as the current FMM technology, the FMM connecting bridge is wider and more difficult to deform, which produces OLED displays with higher pixel density.

Thirdly, the pixel arrangement design and the evaporation method of OLED devices provided by the present disclosure may improve device resolution, operability of the FMM manufacturing and evaporation process, productivity, and yield.

### DESCRIPTION OF DRAWINGS

In order to more clearly illustrate the technical solutions of the embodiments of the present invention, the drawings used in the description of the embodiments will be briefly described as below. Obviously, the drawings described as below are just some embodiments of the present invention. For one of ordinary skill in the art, under the premise of no creative labor, other drawings can also be obtained according to these drawings.

FIG. 1 is a schematic diagram of an evaporation principle of a FMM pixel single layer film in current mass production technology.

FIG. 2 is a schematic diagram of two identical sub-pixels of a same monochrome in the present disclosure.

FIG. 3 is a schematic diagram of RGB pixels disposed on an evaporation substrate in the present disclosure.

FIG. 4 is a schematic diagram of when the RGB pixels are disposed on the evaporation substrate, a number of pixels in three single-color independent units is same, and FMM openings are distributed on a same straight line in the present disclosure.

FIG. 5 is a schematic diagram of when the RGB pixels are disposed on the evaporation substrate, the FMM openings are distributed on a same straight line in the present disclosure.

FIG. 6 is a schematic diagram of the FMM openings in the present disclosure.

FIG. 7 is a principle flowchart of a pixel arrangement evaporation method for improving pixel resolution of an embodiment in the present disclosure.

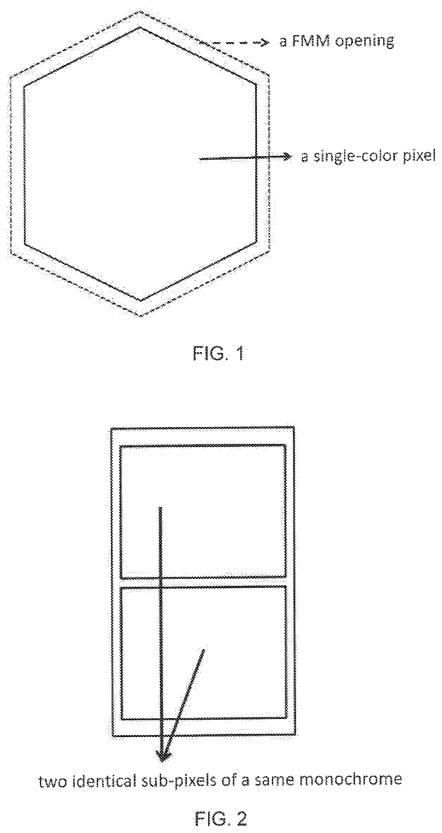

Figure numerals: red quadrangle 1, green quadrangle 2, and blue quadrangle 3.

### DETAILED DESCRIPTION OF PREFERRED EMBODIMENTS

In order to make the objectives, technical solutions, and advantages of embodiments of the present disclosure clearer. The technical solutions in the embodiments of the present disclosure will be clearly and completely described below in conjunction with the accompanying drawings in the embodiments of the present disclosure. Obviously, the embodiments described are merely a part of the present disclosure, rather than all the embodiments. All other embodiments obtained by the person having ordinary skill in the art based on embodiments of the disclosure, without making creative efforts, are within the scope of the present disclosure.

### Embodiment 1

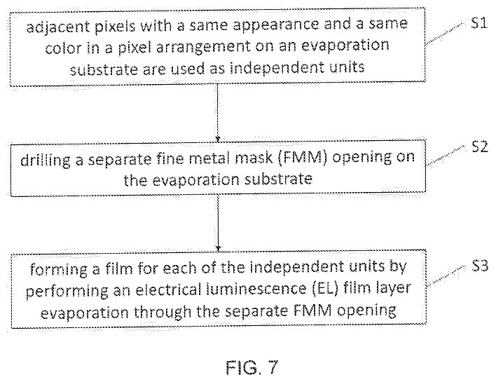

As shown in FIG. 7, the embodiment provides a pixel arrangement evaporation method for improving pixel resolution, and the evaporation method comprises steps as follows:

Step 1 S1 is using adjacent pixels with a same appearance and a same color in a pixel arrangement on an evaporation substrate as independent units.

Step 2 S2 is drilling a separate fine metal mask (FMM) opening on the evaporation substrate.

Step 3 S3 is forming a film for each of the independent units by performing an electrical luminescence (EL) film layer evaporation through the separate FMM opening.

When a number of the pixels in three single-color independent units is same, all the pixel arrangements and independent units are evaporated by a same FMM opening.

During the evaporation process, a plate with evaporation particles and closest to an evaporation source in the substrate is removed, and a clean plate is further added to a restriction unit at a position different from a position of the removed substrate. An opening direction of at least one first FMM opening and at least one second FMM opening is inclined toward an opposite side with one another, so that an amount of an evaporation material attached to the restriction unit is reduced for improving utilization efficiency of the evaporation material.

### Embodiment 2

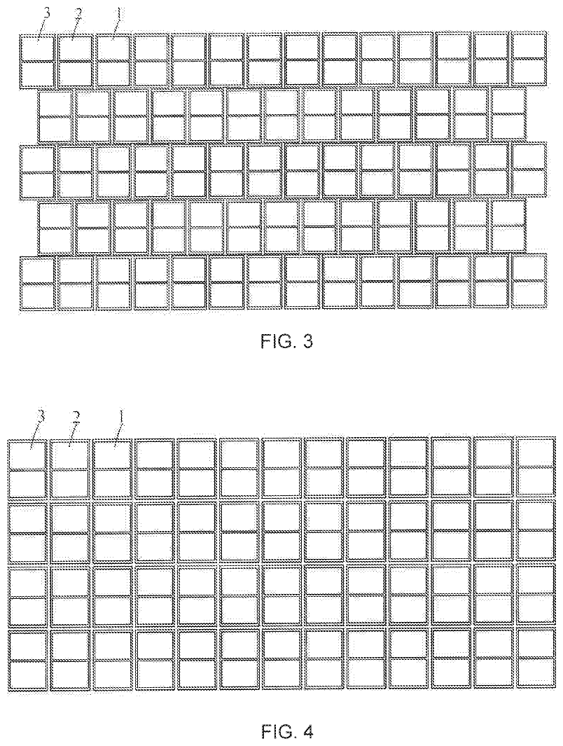

As shown in FIG. 2, the embodiment provides a higher pixel per inch (PPI) OLED device pixel arrangement design and an evaporation method.

The purpose is that during manufacturing of OLED panels with a same resolution, widths of an opening and a connecting bridge are greater, making a mask of red, green, and blue pixels of the present disclosure easier to process and not easy to deform compared with the mask in the current FMM technology An increase in a distance between different pixels is beneficial for preventing color from mixing and improving product yield. Larger margin of evaporation position makes it easy to perform the evaporation process, preventing the reduction of productivity caused by the increase of FMM replacement frequency and reducing loss of FMM due to cleaning.

In other words, in a case where the mask opening width is same as the current FMM technology, a plurality of types of through-holes are formed on a front surface of an evaporation source opening, and limit the opening by a method that an opening width becomes larger as it approaches an evaporation mask from the evaporation source opening. The FMM connecting bridge is wider and difficult to deform, which produces OLED with higher pixel density displays.

In the present embodiment, an organic electrical luminescence (EL) display device is a bottom-emission type organic EL display device that extracts light from a thin film transistor (TFT) substrate side, which controls light emission of pixels (sub-pixels) of each color comprising red (R) pixels, green (G) pixels, and blue (B) pixels to perform full-color image display. A film comprises a main part of the film and a blurred part of the film. The main part of the film is made of evaporation mixed particles, and the blurred part of the film may prevent the occurrence of color mixing and improve the utilization efficiency of evaporation particles materials, and also reduce the frequency of replacement of restriction plate units.

For substrates, first, TFTs and wirings are formed on an insulating substrate by a method in the prior art. A transparent glass substrate or a plastic substrate may be used as the insulating substrate. In one embodiment, a rectangular glass plate with a thickness of about 1 mm and a vertical and horizontal size of 500 mm×400 mm may be used as the insulating substrate. Then, an interlayer film is formed by coating a photosensitive resin on the insulating substrate through a method of covering a thin film transistor (TFT) and a wiring, and patterning by using a photolithography technique.

An insulating material such as an acrylic resin or a polyimide resin may be used as a material of the interlayer film. However, polyimide resins are generally opaque and colored. Therefore, when manufacturing the bottom-emission type organic EL display device, a transparent resin such as the acrylic resin is preferably used as the interlayer film. A thickness of the interlayer film is not particularly limited as long as it can eliminate a step difference on an upper surface of the TFT. In the embodiment, the interlayer film with a thickness of about 2 μm is made of the acrylic resin.

Then, a contacting hole used for electrically connecting an electrode and the TFT is formed on the interlayer film. The electrode is formed on the interlayer film, that is, a conductive film (electrode film) is formed on the interlayer film. Moreover, after coating a photoresist on the conductive film and patterning by using the photolithography technique, the conductive film is etched with an etching solution of ferric chloride. Then, the photoresist is stripped with a resist stripping solution and the substrate is further cleaned. An electron transport layer is formed on an entire surface of a display region of a TFT substrate by the evaporation method. The electron transport layer may be formed by a same method as a hole injection layer and a hole transporting layer. On the other hand, electrons are injected into an organic EL layer. Holes and the electrons are recombined in a light-emitting layer to emit light of a predetermined color when the energy is deactivated. By controlling the light emission brightness of each pixels, a predetermined image may be displayed in a display region 19.

The light-emitting layer may be made of materials with high light-emitting efficiency, such as low-molecular fluorescent pigments and metal complexes, including anthracene, naphthalene, indene, phenanthrene, pyrene, tetracene, benzophenanthrene, anthracene, fluorene, pyrene, fluoranthene, phenanthrene, pentaphene, pentacene, hexabenzobenzene, butadiene, coumarin, acridine, pyrene, and derivatives thereof, tris(8-hydroxyquinoline) aluminum complex, bis(hydroxybenzoquinoline) beryllium complex, tris (dibenzoylmethyl) o-diazaphenanthrene complex, xylyl vinyl biphenyl, etc.

The light emitting layer may comprise the aforementioned organic light emitting material and may also comprise hole transport layer materials, electron transport layer materials, additives (donors, acceptors, etc.), luminescent dopants, etc. In addition, a structure in which these materials are distributed in a polymer material (adhesive resin) or an inorganic material may be used. From the viewpoint of improving luminous efficiency and lifespan, a structure in which the luminescent dopant is distributed in a host material is preferable.

In the present embodiment, two sub-pixels with same R, G, and B are arranged together as an independent unit. The unit may be evaporated through an FMM opening, but the sub-pixels emit light separately. A distance between same sub-pixels in the independent unit may be reasonably reduced when the R, G, and B pixels are manufactured by the above mask. A distance between the corresponding unit thereof and adjacent different unit thereof is increased.

### Embodiment 3

The present embodiment provides a pixel arrangement display device and an evaporation method for improving pixel resolution. A quadrangle of R pixels, G pixels, and B pixels that may be independently controlled and emitted are arranged on the evaporation substrate in order. Adjacent pixels with a same appearance and a same color in a pixel arrangement on an evaporation substrate are used as independent units, and a film is formed for each of the independent units by performing an EL film layer evaporation through the separate FMM opening. The EL film layer is made of heterocyclic or chain conjugated monomers, oligomers, or polymers, such as phenyne, styrylamine, triphenylamine, porphyrin, triazole, imidazole, oxadiazole, polyarylalkane, phenylenediamine, arylamine, oxazole, anthracene, fluorenone, fluorene, amidine, benzophenanthrene, azabenzophenanthrene and their derivatives, polysilane compounds, vinylcarbazole compounds, thiophene compounds, and aniline compounds.

Various combinations can be considered for types of organic EL layers constituting an organic EL element and materials of each layer constituting the organic EL layers. For example, forming a light-emitting layer in which a luminescent dopant is distributed in a host may be considered. In this case, a material having a good electron transport efficiency (that is, an electron transporting material) may be used in the host, or a material having a property of blocking hole movement (that is, a hole blocking property) may be used in the host.

The arrangement of R, G, and B pixels on the evaporation substrate is shown in FIG. 3. The R pixels are red quadrangle 1, the G pixels are green quadrangle 2, and the B pixels are blue quadrangle 3.

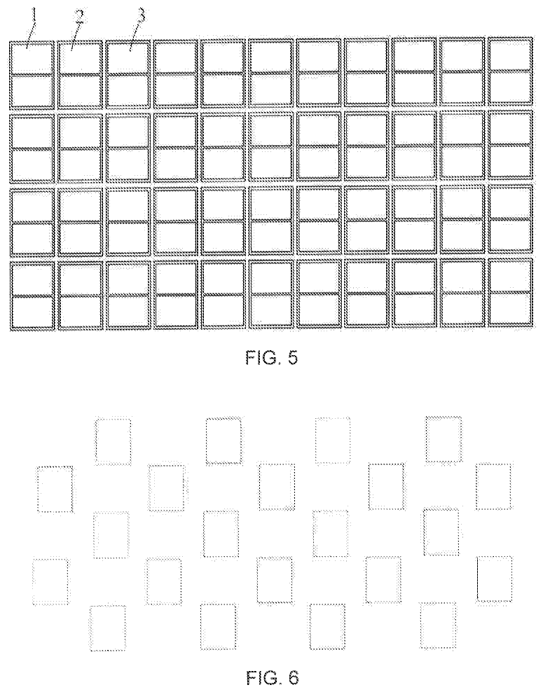

The FMM opening is as shown in FIG. 6. The openings include but are not limited to quadrilaterals. Pixel appearance and size of independent units are same, and the pixel appearance and size in different colored units may be same or different. The number of pixels in the independent units is ≥2, and it includes but is not limited to the ones described in present disclosure. As long as the number of the pixels in three single-color independent units is same, and all the pixel arrangements and independent units are evaporated by a same FMM opening. As shown in FIG. 3, FIG. 4, and FIG. 5, the FMM openings may be distributed on a same straight line or on a different straight line.

### Embodiment 4

In the present embodiment, the R, G, and B pixels arrangement design on the substrate is used in areas including EL film layer formation using the evaporation process, but is not limited to the evaporation process. During the evaporation process, a plate with evaporation particles closest to an evaporation source in the substrate is removed, and a clean plate is further added to a restriction unit at a position different from a position of the removed substrate. When an evaporation material is attached to the restriction unit, only the plate closest to the evaporation source with the largest amount of evaporation material attached may be removed. As a result, it easily maintains the restriction unit in a short amount of time and increases the accuracy of evaporation. Because the clean plate is added at the location different from the location where the plate to which the evaporation material was attached, it is possible to lengthen the usage period of each of a plurality of plate materials in the restriction unit until the evaporation material is taken out.

An opening direction of at least one first FMM opening and at least one second FMM opening is inclined toward an opposite side with one another, so that an amount of an evaporation material attached to the restriction unit is reduced for improving utilization efficiency of the evaporation material. In addition, the frequency of replacement of the restriction plate units is reduced, which may increase the productivity during mass production and reduce the overall size and weight of the restriction plate units, realizing easy replacement of restriction limit plate units, Moreover, the cooling characteristics of the restriction plate unit are improved, so that the flying direction of the evaporation particles may be stably controlled.

To prevent the evaporation material from evaporation again, the restriction plate unit comprises a cooling device for cooling the restriction plate unit, and the cooling device is not particularly limited, for example, a piping for passing a refrigerant (such as water), a cooling element such as a Peltier element, etc. may be arbitrarily selected. The evaporation material adheres to the restriction plate unit. Thus, it is preferable to replace the restriction plate unit to which the evaporation material is attached with a new restriction plate unit within a predetermined period.

In order to easily replace the restriction plate unit, the restriction plate unit may adopt a structure capable of being divided into a plurality of parts. In the present embodiment, a fractional evaporation of the light-emitting layer is performed to prevent color from mixing. Thus, an interval of pixels may be reduced, and in this case, it may provide an organic EL display device with high-definition display. On the other hand, the interval of pixels may also not be changed to expand the light-emitting region, and in this case, it may provide an organic EL display device with high-brightness display. In addition, since it is not necessary to increase the current density for high-brightness, the organic EL element does not shorten its life or suffer damage, and may prevent a decrease in reliability.

The pixel arrangement design and the evaporation method of OLED devices provided by the present embodiment may improve device resolution, operability of the FMM manufacturing and evaporation process, productivity, and yield.

The above embodiments are only used to illustrate the technical solutions of the present disclosure, but not to limit it. Although the present disclosure has been described in detail with reference to the foregoing embodiments, those of ordinary skill in the art should understand that the technical solutions described in the aforesaid embodiments can still be modified, or have some technical features equivalently replaced. However, these modifications or replacements do not depart from a scope of the technical solutions of the embodiments of the present disclosure.

What is claimed is:

1. A pixel arrangement evaporation method for improving pixel resolution, comprising steps as follows:
step 1: utilizing adjacent pixels with a same appearance and a same color in a pixel arrangement on an evaporation substrate as independent units;
step 2: drilling a separate fine metal mask (FMM) opening on the evaporation substrate; and
step 3: forming a film for each of the independent units by performing an electrical luminescence (EL) film layer evaporation through the separate FMM opening.

2. The pixel arrangement evaporation method for improving pixel resolution as claimed in claim 1, wherein when a number of the pixels in three single-color independent units is same, all the pixel arrangements and independent units are evaporated by a same FMM opening.

3. The pixel arrangement evaporation method for improving pixel resolution as claimed in claim 1, wherein during the evaporation process, a plate with evaporation particles closest to an evaporation source in the substrate is removed, and a clean plate is further added to a restriction unit at a position different from a position of the removed substrate.

4. The pixel arrangement evaporation method for improving pixel resolution as claimed in claim 3, wherein an opening direction of at least one first FMM opening and at least one second FMM opening is inclined toward an opposite side with one another, so that an amount of an evaporation material attached to the restriction unit is reduced for improving utilization efficiency of the evaporation material.

5. The pixel arrangement evaporation method for improving pixel resolution as claimed in claim 1, wherein before the step 1, further comprises:
providing an insulating substrate;
forming an interlayer film by coating a photosensitive resin on the insulating substrate through a method of covering a thin film transistor (TFT) and a wiring, and patterning by using a photolithography technique;
forming a contacting hole used for electrically connecting an electrode and the TFT on the interlayer film;
forming a conductive film on the interlayer film; and
patterning the conductive film.

6. The pixel arrangement evaporation method for improving pixel resolution as claimed in claim 5, wherein the interlayer film is an acrylic resin or a polyimide resin.

7. The pixel arrangement evaporation method for improving pixel resolution as claimed in claim 5, wherein a thickness of the interlayer film is 2 μm.

8. A pixel arrangement display device for improving pixel resolution, used for achieving the evaporation method for improving pixel resolution as claimed in claim 1, wherein the display device comprises an electrical luminescence (EL) display device, and the EL display device is a bottom-emission type organic EL display device that extracts light from an evaporation substrate side, which controls light emission of pixels of each color comprising red (R) pixels, green (G) pixels, and blue (B) pixels for performing full-color image display;
a quadrangle of R pixels, G pixels, and B pixels that may be independently controlled and emitted are arranged on the evaporation substrate in order; and
the adjacent pixels with the same appearance and the same color in the pixel arrangement on the evaporation substrate are used as independent units.

9. The pixel arrangement display device for improving pixel resolution as claimed in claim 8, wherein a shape of the FMM opening is a quadrangle or a polygon other than the quadrangle.

10. The pixel arrangement display device for improving pixel resolution as claimed in claim 9, wherein the FMM openings may be distributed on a same straight line.

11. The pixel arrangement display device for improving pixel resolution as claimed in claim 8, wherein a number of pixels in the independent units is ≥2.

12. The pixel arrangement display device for improving pixel resolution as claimed in claim 11, wherein a distance between pixels in the independent units may be increased or decreased.

13. The pixel arrangement display device for improving pixel resolution as claimed in claim 8, wherein the R pixels are red quadrangle, the G pixels are green quadrangle, and the B pixels are blue quadrangle.

14. The pixel arrangement display device for improving pixel resolution as claimed in claim 8, wherein the EL film layer is made of heterocyclic or chain conjugated monomers, oligomers, or polymers, such as phenyne, styrylamine, triphenylamine, porphyrin, triazole, imidazole, oxadiazole, polyarylalkane, phenylenediamine, arylamine, oxazole, anthracene, fluorenone, fluorene, amidine, benzophenanthrene, azabenzophenanthrene and their derivatives, polysilane compounds, vinylcarbazole compounds, thiophene compounds, and aniline compounds.
